(19) United States
(12) Patent Application Publication
(10) Pub. No.: US 2007/0096186 A1
(43) Pub. Date: May 3, 2007

(54) Vertical transistor device and fabrication method thereof

(75) Inventors: Shian-Jyh Lin, Chiayi County (TW); Sheng-Tsung Chen, Tainan (TW); Neng-Tai Shih, Taipei (TW)

Correspondence Address: QUINTERO LAW OFFICE, PC, 2210 MAIN STREET, SUITE 200, SANTA MONICA, CA, 90405, US

(73) Assignee: NANYA TECHNOLOGY CORPORATION, TAOYUAN (TW)

(21) Appl. No.: 11/366,107

(22) Filed: Mar. 1, 2006

(30) Foreign Application Priority Data
Nov. 3, 2005 (TW) TW94138553

(51) Int. Cl. H01L 29/94; H01L 27/108; H01L 29/76; H01L 31/119

(52) U.S. Cl. 257/302

(57) ABSTRACT

A vertical transistor device and fabrication method thereof are provided, the vertical transistor device comprising a substrate having a deep trench. A capacitor is disposed in a lower portion of the deep trench. A conductive structure is disposed on the capacitor inside the deep trench. An epitaxial layer, having an epitaxial sidewall region, is disposed on the substrate. A vertical gate structure is disposed on the conductive structure and adjacent to the epitaxial sidewall region of the epitaxial layer.

### BACKGROUND OF THE INVENTION

1. Field of the Invention

The invention relates to vertical transistors, and in particular to a vertical transistor device with transistors and capacitors and fabrication method thereof.

2. Description of the Related Art

Reduced size, high speed performance and large memory capacity are important for dynamic random access memory (DRAM).

Most DRAMs, used as a memory device, with capacity exceeding 256 or 512 MB, comprise transistors and capacitors. Higher integration is needed for a high-capacity high-speed DRAM as the size thereof decreases. However, much surface area is occupied by conventional transistors and plane capacitors, such that a DRAM with higher integration is difficult to fabricate.

Vertical transistors and trench capacitors have thus been developed and become common in DRAM fabrication. However, current leakage in buried straps and difficulties in controlling channel length are found in conventional vertical transistors. Lower capacitance and charge loss further occur in conventional trench capacitors of polysilicon by recess etching.

Thus, an improved vertical transistor device and fabrication method thereof is called for.

### BRIEF SUMMARY OF THE INVENTION

A detailed description is given in the following embodiments with reference to the accompanying drawings.

In an embodiment, a vertical transistor device is provided, comprising a substrate having a deep trench. A capacitor is disposed in a lower portion of the deep trench. A conductive structure is disposed on the capacitor inside the deep trench. An epitaxial layer, having an epitaxial sidewall region, is disposed on the substrate. A vertical gate structure is disposed on the conductive structure and adjacent to the epitaxial sidewall region of the epitaxial layer.

A method of fabricating a vertical transistor device is also provided. A substrate is provided. A deep trench is formed in the substrate. A capacitor is formed inside a lower portion of the deep trench. A conductive structure is formed on the capacitor inside the deep trench. An epitaxial layer is formed on a surface of the substrate and has an epitaxial sidewall region. A vertical gate structure is formed on the conductive structure and adjacent to the epitaxial sidewall region.

### BRIEF DESCRIPTION OF THE DRAWINGS

The invention can be more fully understood by reading the subsequent detailed description and examples with references made to the accompanying drawings, wherein:

FIGS. 1A and 1B are respectively cross-sections of vertical transistor devices shown in FIG. 1C along the lines 1a to 1a′ and 1b to 1b′ in an embodiment of the invention.

FIG. 1C is a layout of vertical transistor devices in an embodiment of the invention.

FIGS. 2A, 2B, 3A, 3B, 4A, 4B, 5A and 5B show preparations of a vertical transistor device in an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

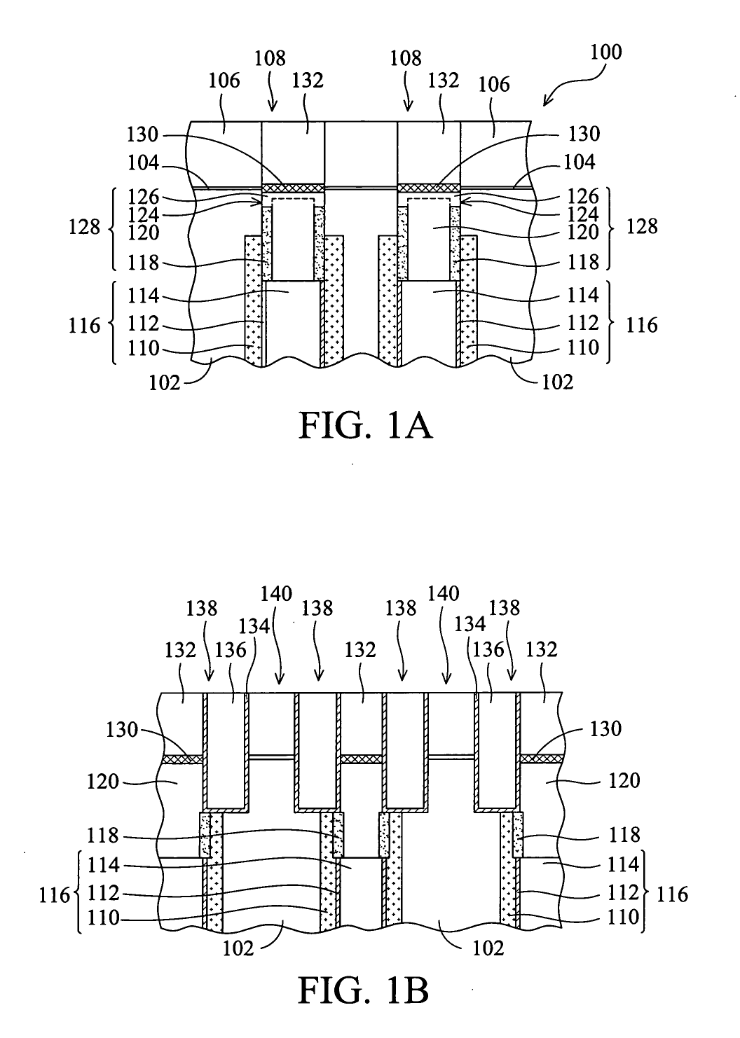

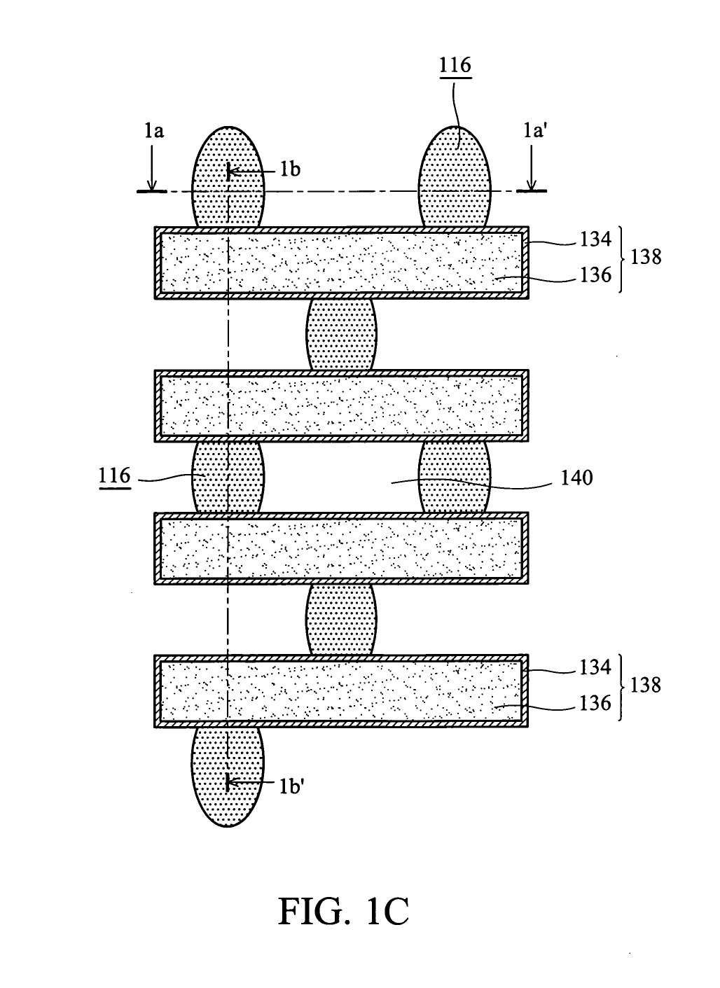

FIG. 1C is a layout of vertical transistor devices in an embodiment of the invention, comprising capacitor 116, shallow trench isolation (STI) 138 and active area 140. FIGS. 1A and 1B are respectively cross-sections of vertical transistor devices shown in FIG. 1C along the line 1a to 1a′ and 1b to 1b′.

A method of fabricating the structure shown in FIG. 1A follows.

As shown, substrate 102 comprising silicon is provided. Pad layers, such as a pad layer 104 of silicon oxide and pad layer 106 of silicon nitride, are respectively formed on the substrate 102. Deep trenches 108 are formed in the substrate 102 by photolithography and reactive ion etching (RIE) using the pad layers 104 and 106 as a mask.

After forming the trenches 108, capacitors 116 are formed. Each capacitor 116 comprises a buried bottom electrode 110, node dielectric layer 112 and top electrode 114.

In an embodiment, a heavily doped oxide layer (not shown), such as arsenosilicate glass (ASG), is deposited on lower portions of the deep trench 108. N-type ions, such as As⁻, are propelled and diffuse into the substrate 102 near lower portions of the deep trench 108, by rapid thermal process (RTP), and the buried bottom electrode 110 is formed.

After the buried bottom electrode 110 is formed, a node dielectric layer 112 of silicon oxide, silicon nitride or other high-k dielectric is formed on sidewall and bottom portions of the deep trench 108. A top electrode 114, also referred to as a storage node, of polysilicon comprising n-type dopant, is formed in the deep trench 108.

After the capacitor 116 is formed, a conductive structure 128 comprising a collar dielectric 118, conductive layer 120, buried strap (BS) 126, and buried strap nitride 124 (not shown) is formed in the deep trench 108.

A collar dielectric 118 is formed on the capacitor 116 and on a sidewall of the deep trench 108 as follows. A silicon oxide layer is deposited on the substrate 102, compacted by rapid thermal process, and etched to expose the top electrode 114 and the upper portion of the pad layer 106 by dry etching. The collar dielectric 118 covers a portion of the sidewall of the deep trench 108 and the sidewall of the pad layer 104 to prevent the pad layer 104 from damage by subsequent process. (A portion of the collar dielectric 118 covering the pad layer 104 is removed in subsequent process.)

After forming the collar dielectric 118, a conductive layer 120 is formed in the deep trench 108, adjacent to the top electrode 114 and surrounded by the collar dielectric 118. The conductive layer 120 is electrically connected to the substrate 102 and other circuit through subsequently formed buried strap 126.

In an embodiment, a polysilicon layer is formed on the substrate 102, filling the deep trench 108. A portion of the polysilicon layer above the pad layer 106 is removed to expose the surface thereof by chemical mechanical polishing (CMP). The remaining polysilicon layer is etched to a predetermined level lower than the surface of the substrate 102 by wet recess or dry stripping.

After the conductive layer 120 is formed, a portion of the collar dielectric 118 is removed to a predetermined level below the surface of the conductive layer 120 by wet etching. Thickness of the removed portion of the collar dielectric 118 determines current amount and carrier storage time of the capacitor 116, since current flows through the path indicated by the arrow 124 shown in FIG. 1A.

A buried strap nitridation (not shown, located indicated by the arrow 124 shown in FIG. 1A) is optionally formed on a sidewall of the deep trench 108 above the collar dielectric 118 in an embodiment of the invention. Current flow and ion diffusion degree are controlled using the buried strap nitridation.

After a portion of the collar dielectric 118 is removed, a buried strap 126 is formed on the collar dielectric 118 and adjacent to a top portion of the conductive layer 120, electrically connecting the capacitor 116 and other circuit.

In an embodiment, a polysilicon layer is deposited on the conductive layer 120 and the substrate 102. A slot, between the conductive layer 120 and the substrate 102, formed previously upon etching the collar dielectric 118, are filled by the polysilicon layer. The polysilicon layer is partially removed to a predetermined level near and preferably slightly lower than the top surface of the substrate 102 to expose the pad layers 104 and 106 by wet etching.

After the buried strap 126 is formed, a trench top insulator 130, also referred to as trench top oxide (TTO), is formed on the conductive structure 128 and near the top surface of the substrate 102. Electrical interference between capacitor 116 and subsequently formed gate electrodes is prevented by trench top insulator 130 having a sufficient thickness.

In an embodiment, a silicon oxide layer is deposited on the substrate 102 to fill the deep trench 108 and cover the conductive structure 128. The silicon oxide layer can be formed by HDP-CVD or thermal oxidation. The silicon oxide layer is then removed to a predetermined level slightly higher than the top surface of the pad layer 104 by wet etching.

Referring to FIGS. 1A to 1C, after forming the trench top insulator 130, STIs 138 and active areas 140 are defined by a polysilicon layer 132 deposited on the substrate 102 to fill the deep trench 108 above the trench top insulator 130. A portion of the polysilicon layer 132 is removed to expose the pad layer 106 by CMP. A boron silicate glass (BSG, not shown) layer and a hard mask layer (not shown) of polysilicon are respectively deposited on the substrate 102. The two deposited layers are patterned and partially removed, and STI trenches formed. A liner 134 is deposited to conformally cover sidewalls and bottoms of the STI trenches, and a silicon oxide layer 136 is deposited on the substrate 102 and the liner 134 to fill the STI trenches by HDP-CVD. A portion of the liner 134 and the silicon oxide layer 136 are removed to expose the pad layer 106 and polysilicon layer 132 by CMP. As shown in FIG. 1B, an upper portion of the conductive structure 128 is inserted by a STI 138.

While a conventional trench top insulator is formed under the substrate surface, the trench top insulator 130 according to the invention is formed close to the top surface of the substrate 102, such that the profiles of the STIs 138 and the silicon oxide layer 136 are easily controlled, fewer defects are formed during fabrication, and capacitance of the capacitor 116 is enhanced since surface area and utilization rate thereof is increased.

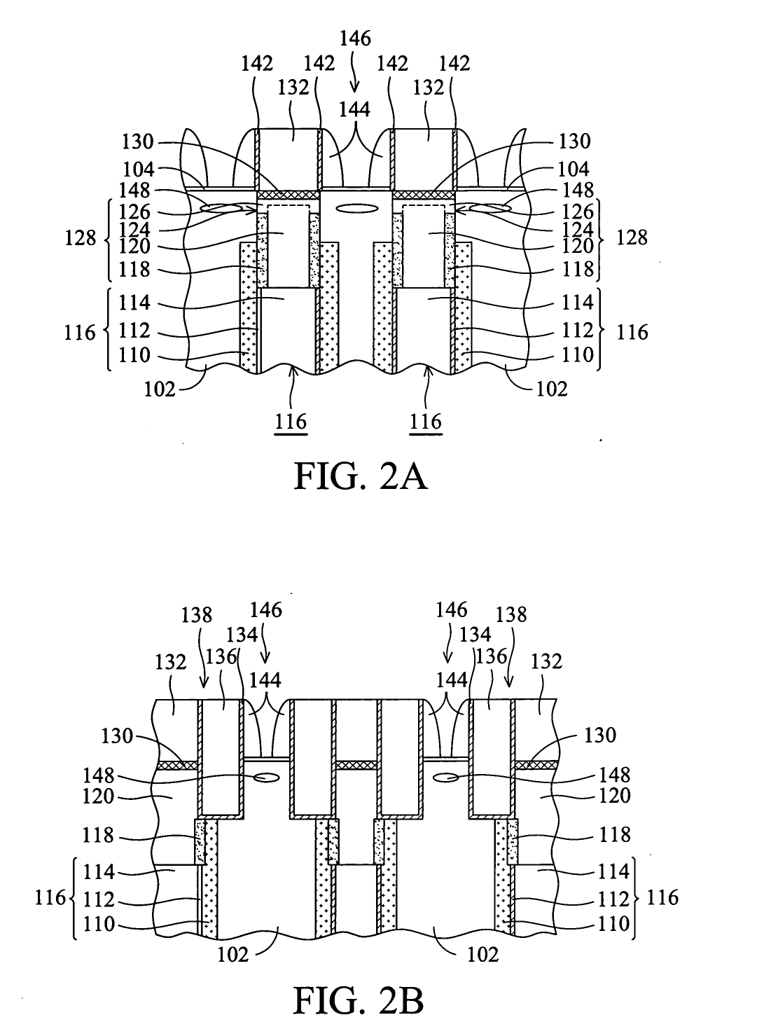

Referring to FIGS. 2A and 2B, after forming the STIs 138, a buried strap isolation 148 are formed in the substrate 102 and between two adjacent deep trenches 108.

In an embodiment, the pad layer 106 is removed to expose the pad layer 104 and sidewall of the polysilicon layer 132 by wet etching. A sidewall of the polysilicon layer 132 is oxidized to form a sidewall oxide layer 142. A silicon nitride layer is deposited on the substrate 102 and then recessed to form spacers 144, exposing a partial surface of the pad layer 104. The substrate 102 is implanted to form buried strap isolations 148 by self-aligned implantation 146 with a dopant, such as boron or indium, through the pad layer 104 to the substrate 102.

A buried strap diffusion region (not shown) is formed in the substrate 102 adjacent to the buried strap 126 since ions contained in the buried strap 126 diffusing into the substrate 102 remain therein. The buried strap diffusion region can act as source region or drain region. Current leakage from connection of buried strap diffusion regions between two adjacent deep trenches 108 is prevented by formation of the buried strap isolation 148. The position of the buried strap isolation 148 and dopant dose contained therein can be accurately controlled since the trench top insulator 130 is formed near the top surface of the substrate 102 and ion implantation is self-aligned.

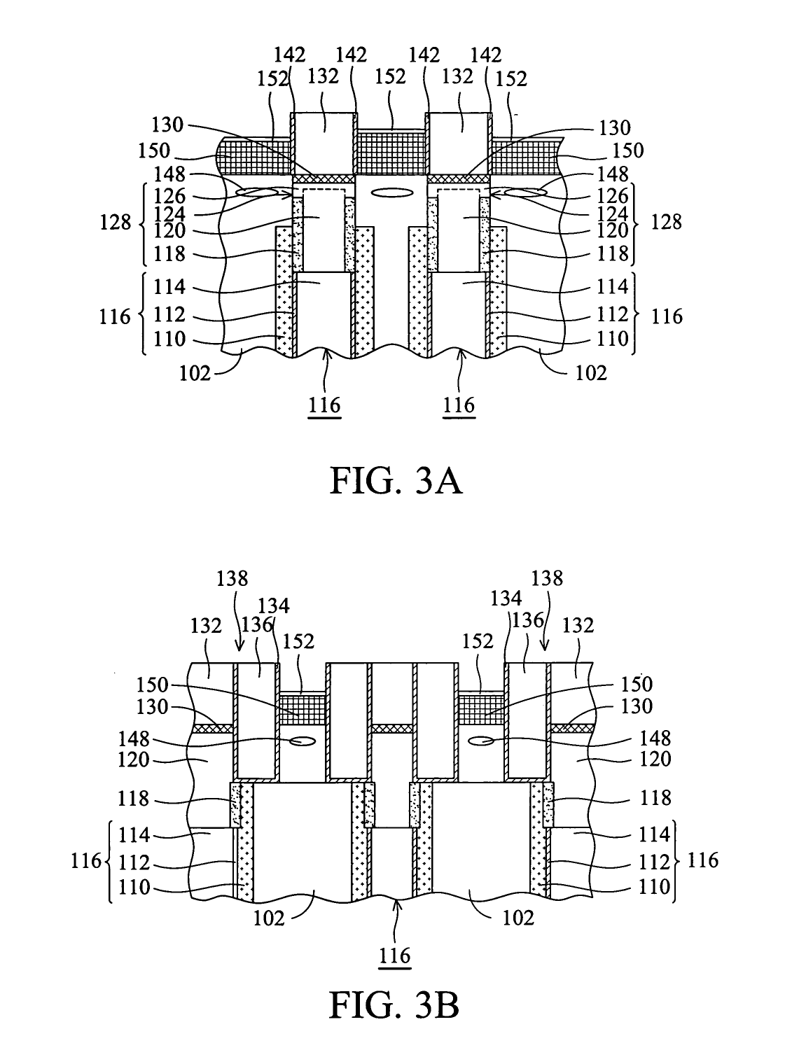

Referring to FIGS. 3A and 3B, after forming the buried strap isolation 148, an epitaxial layer 150 with a sidewall region is formed on the substrate 102. The sidewall region can be used as a channel region, and the thickness of the epitaxial layer 150 can be regarded as a channel length of the channel region. The channel length can be accurately controlled since the epitaxial layer 150 is formed by selective epitaxial growth (SEG).

The epitaxial layer 150 is formed by spacers 144 as shown in FIG. 2A being removed by wet etching, and pad layer 104 being removed. Referring to FIG. 3A, the epitaxial layer 150 of selective epitaxial silicon layer is formed on the substrate 102 by SEG. An oxide layer 152 is formed by oxidizing exposed epitaxial layer 150, and an ion implantation (not shown) is then applied to the active area to form a source or drain region.

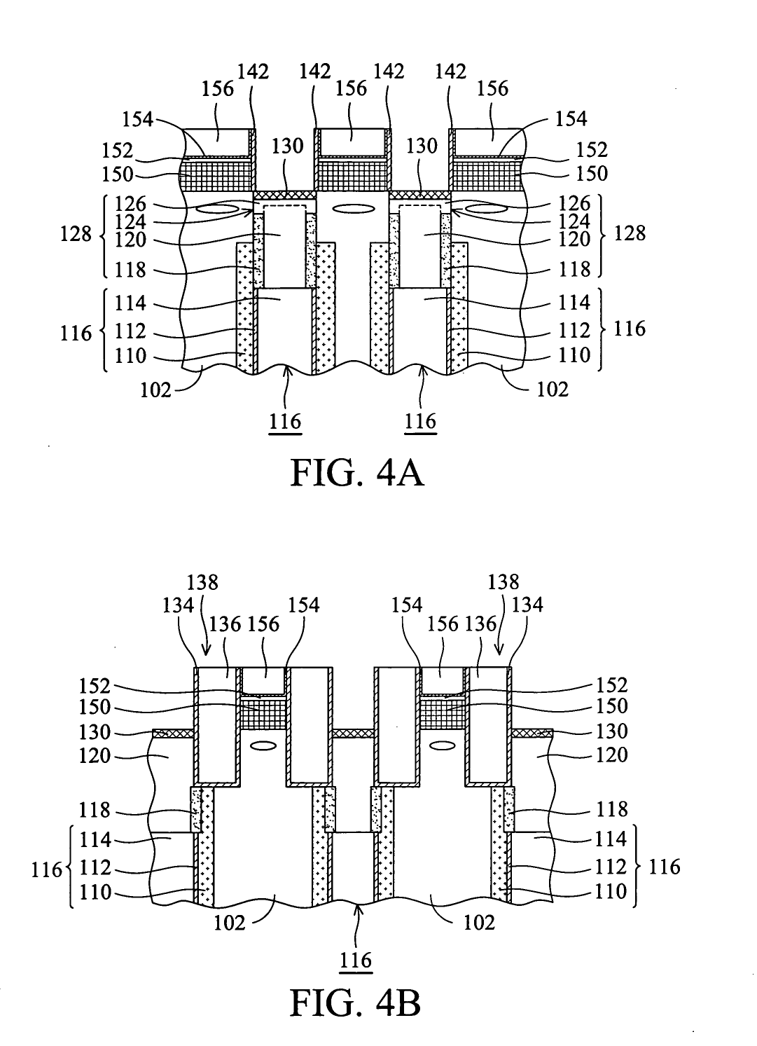

Referring to FIGS. 4A and 4B, a liner 154 of silicon nitride is deposited on the substrate 102, and array top oxide 156 is deposited on the liner 154. The liner 154 and array top oxide 156 protect the epitaxial layer 150 from damage in subsequent process. Planarization such as CMP, removes excess array top oxide 156. The polysilicon layer 132 is removed to expose the trench top insulator 130 by wet or dry etching.

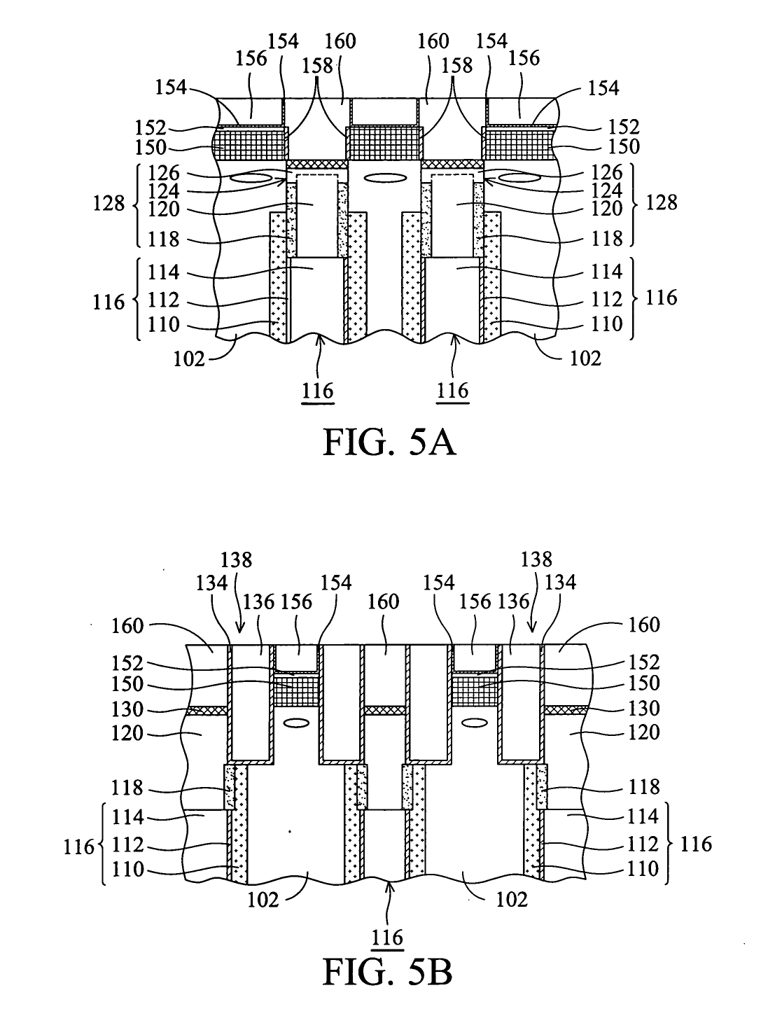

Referring to FIGS. 5A and 5B, after removing the polysilicon layer 132, a vertical gate structure is formed on the trench top insulator 130 and adjacent to the sidewall region of the epitaxial layer 150. The vertical gate structure comprises a gate dielectric 158, gate electrode 160, channel region (not shown), source region and drain region (not shown). The gate dielectric 158 is disposed on the sidewall region of the epitaxial layer 150. The gate electrode 160 is disposed on the trench top insulator 130 and next to the gate dielectric 158. The source region and drain region are respectively disposed in a top portion and a bottom portion of the sidewall region of the epitaxial layer 150. The channel region (not shown) having a channel length extending from the source region to the drain region.

In an embodiment, the sidewall oxide layer 142 as shown in FIG. 4A is removed by wet etching. Referring to FIG. 5A, the gate dielectric 158 is formed by oxidizing the sidewall of the epitaxial layer 150. The gate electrode 160 is formed by filling a conductive material, such as polysilicon, into the deep trench 108. Excess conductive material is removed by CMP.

In another embodiment, the gate electrode 160 is formed by forming a thin polysilicon layer on the substrate 102, and then depositing a conductive material, such as TiN, WN, WSi or W, by atomic layer deposition (ALD), physical vapor deposition (PVD) or chemical vapor deposition (CVD). In this embodiment, resistance of the gate electrode 160 is reduced, operating speed of a DRAM is enhanced, and greater current can be loaded by a vertical gate structure.

In conventional formation of vertical transistor devices, a vertical gate structure is formed before forming an active area. However, according to the invention, a vertical gate structure is formed after forming an active area, such that accuracy and convenience of fabricating components in an active area are enhanced since they are not affected by a vertical gate structure during fabrication. Damages in gate dielectrics can also be prevented.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A vertical transistor device, comprising:
a substrate having a deep trench;
a capacitor disposed in a lower portion of the deep trench;
a conductive structure disposed on the capacitor inside the deep trench;
an epitaxial layer, having an epitaxial sidewall region, disposed on the substrate; and
a vertical gate structure disposed on the conductive structure and adjacent to the epitaxial sidewall region of the epitaxial layer.

2. The device of claim 1, wherein the capacitor comprises:
a buried bottom electrode disposed in a lower portion of the deep trench in the substrate;
a node dielectric layer disposed on a bottom and a sidewall of the deep trench, and adjacent to the buried bottom electrode; and
a top electrode disposed inside the deep trench and surrounded by the node dielectric layer.

3. The device of claim 1, wherein the conductive structure comprises:
a conductive layer contacting the capacitor;
a collar dielectric disposed on a sidewall of the deep trench and surrounding a lower portion of the conductive layer; and
a buried strap disposed on the collar dielectric and adjacent to a top portion of the conductive layer.

4. The device of claim 1, further comprising a trench top insulator disposed on the conductive structure and close to a top surface of the substrate.

5. The device of claim 4, wherein the trench top insulator comprises a high density plasma oxide layer or thermal silicon oxide layer.

6. The device of claim 1, further comprising a buried strap isolation disposed in the substrate and between two adjacent deep trenches.

7. The device of claim 6, wherein the buried strap isolation is formed by implanting a dopant using self-aligned ion implantation.

8. The device of claim 7, wherein the dopant comprises boron or indium.

9. The device of claim 1, wherein the epitaxial layer comprises a selective epitaxial silicon layer.

10. The device of claim 1, wherein the vertical gate structure comprises:
a gate dielectric disposed on the epitaxial sidewall region;
a gate electrode disposed on the trench top insulator and next to the gate dielectric;
a source region and a drain region respectively disposed in a top portion and a bottom portion of the epitaxial sidewall region; and
a channel region having a channel length extending from the source region to the drain region.

11. The device of claim 10, wherein the gate electrode comprises polysilicon, titanium nitride, tungsten nitride, tungsten silicide, tungsten or metal compound.

12. A method of fabricating a vertical transistor device, comprising:
providing a substrate;
forming a deep trench in the substrate;
forming a capacitor inside a lower portion of the deep trench;
forming a conductive structure on the capacitor inside the deep trench;
growing an epitaxial layer on a surface of the substrate, the epitaxial layer having an epitaxial sidewall region; and
forming a vertical gate structure on the conductive structure and adjacent to the epitaxial sidewall region.

13. The method of claim 12, wherein forming the deep trench comprises:
depositing a pad layer on the substrate;
patterning the pad layer; and
etching the substrate, using the pad layer as a mask, to form the deep trench.

14. The method of claim 12, wherein forming the capacitor comprises:
forming a buried bottom electrode in a lower portion of the deep trench in the substrate;
forming a node dielectric layer on a bottom and a sidewall of the deep trench, the node dielectric layer adjacent to the buried bottom electrode; and
forming a top electrode inside the deep trench, the top electrode surrounded by the node dielectric layer.

15. The method of claim 12, wherein forming the conductive structure comprises:
forming a collar dielectric on a sidewall of the deep trench and above the capacitor;
forming a conductive layer inside the deep trench, wherein the conductive layer is adjacent to the capacitor and comprises a lower portion surrounded by the collar dielectric; and
forming a buried strap on the collar dielectric, adjacent to a top portion of the conductive layer.

16. The method of claim 12, further comprising forming a trench top insulator on the conductive structure and adjacent to a top surface of the substrate.

17. The method of claim 16, wherein the trench top insulator is formed by depositing a silicon oxide layer using high density plasma chemical vapor deposition.

18. The method of claim 12, further comprising forming a buried strap isolation in the substrate and between two adjacent deep trenches.

19. The method of claim 18, wherein the buried strap isolation is formed by implanting a dopant using self-aligned ion implantation.

20. The method of claim 19, wherein the dopant comprises boron or indium.

21. The method of claim 12, wherein the epitaxial layer comprises selective epitaxial silicon layer formed by epitaxial growth.

22. The method of claim 12, wherein forming the vertical gate structure comprises:
forming a gate dielectric on the epitaxial sidewall region;
forming a gate electrode on the trench top insulator and next to the gate dielectric; and
respectively forming a source region and a drain region in a top portion and a bottom portion of the epitaxial sidewall region;
wherein the vertical gate structure comprises a channel region having a channel length extending from the source region to the drain region.

23. The method of claim 22, wherein the gate dielectric comprises silicon oxide formed by thermal oxidation.

24. The method of claim 22, wherein the gate electrode comprises polysilicon, titanium nitride, tungsten nitride, tungsten silicide, tungsten or metal compound formed by physical vapor deposition or chemical vapor deposition.
